(19) United States
(12) Patent Application Publication
(10) Pub. No.: US 2026/0171905 A1
(43) Pub. Date: Jun. 18, 2026

(54) Power Converter Device

(71) Applicant: Infineon Technologies Austria AG, Villach (AT)

(72) Inventors: Kevin TOMAS MANEZ, Villach (AT); Borja-Vicente PANO MARIN, München (DE); Juan Miquel MARTINEZ SANCHEZ, Villach (AT)

(21) Appl. No.: 19/414,615

(22) Filed: Dec. 10, 2025

(30) Foreign Application Priority Data
Dec. 13, 2024 (DE) 102024137664.3

(51) Int. Cl. H02M 3/00; H02M 3/335; H05K 7/14; H05K 7/20

(52) U.S. Cl. CPC H02M 3/003; H05K 7/1432; H05K 7/209; H02M 3/33573; H02M 3/33576

(57) ABSTRACT

A power converter device comprises: a first substrate comprising a first circuit, wherein the first circuit comprises at least one switching cell, which is arranged as semiconductor material in at least one integrated electronic device; and a second substrate comprising a second circuit, wherein the first substrate and the second substrate are connected to each other through a connection of the integrated electronic device and the second circuit.

### RELATED APPLICATIONS

This application claims priority to earlier filed German Patent Application Serial Number 10 2024 137 664.3, filed on Dec. 13, 2024, the entire teachings of which are incorporated herein by this reference.

### TECHNICAL FIELD

This specification refers to embodiments of a power converter device.

### BACKGROUND

Power converter devices are essential electronic circuits that play a critical role in modern power management systems. Their primary function is to convert the voltage of a current source from one level to another, ensuring stable and efficient power delivery to various electronic devices and systems. Power converter devices such as DC to DC converters are in high demand in fast developing industries such as data centers, automotive, consumer electronics, and industrial machinery and vehicles, where DC to DC converters must meet extremely high standards.

The implementation of power converter devices typically faces several technical challenges to achieve requirements regarding miniaturization and power density, performance enhancement, such as reducing losses, reducing parasitic components, and layout optimization, thermal management, integration complexity, cost, etc.

Several power converter designs are known in the prior art, such as:

A power converter device realized on a single substrate with Surface-Mounted Devices, SMDs, and reactive components mounted on the substrate, which can be manufactured in a simple and widely adopted manufacturing process. However, mounting all components of the power converter device on a single substrate requires a lot of space on the substrate. Optimizing thermal and electrical performance of such a single substrate assembly can be challenging. In addition, the stacking of the substrate, for example the stacking of PCB boards, of the conventional assembly is determined by the requirements of the transformer.

Power converter devices where bare dies or prepackaged transistors are embedded in a PCB substrate don't require much space, switching loop characteristics can be reduced, and thermal management can be improved. However, the manufacturing process can be complex, since the requirements for embedding semiconductors in a PCB substrate can be in conflict with the requirements for integrating magnetics into the same PCB.

Power converter devices that are located on multiple substrates, e.g. PCB boards, can overcome the design challenges mentioned above in regard to embedding semiconductors in a substrate. In particular, the transformer and other reactive components can be placed on a substrate, while the semiconductors are placed on a different substrate. Both substrates are typically interconnected through mechanical parts, such as copper blocks or castellated vias.

### BRIEF DESCRIPTION

This disclosure includes the observation that the process of interconnecting the substrates using mechanical parts can be complex, and the resulting power converter device can still have a relatively large form factor.

Therefore, there is a need for an improved power converter device that overcomes the above-mentioned issues.

According to an embodiment, a power converter device comprises: a first substrate comprising a first circuit, wherein the first circuit comprises at least one switching cell, which is arranged as semiconductor material in at least one integrated electronic device; and a second substrate comprising a second circuit, wherein the first substrate and the second substrate are connected to each other through a connection of the integrated electronic device and the second circuit.

In an example, the switching cell comprises a Metal-Oxide-Semiconductor Field-Effect-Transistor, MOSFET.

In an example, the integrated electronic device is configured as a dissipative package, in particular as a dual side cooling package, encapsulating the semiconductor material in an insulating material.

In an example, a first side of the integrated electronic device includes at least a first access terminal of the first circuit, wherein the first access terminal is connected to the second circuit. In this example, a second side, opposite to the first side, includes at least a second access terminal, in particular a source or drain terminal, wherein the second access terminal is connected to the first substrate, in particular to a strip conductor on the first substrate.

In an example, the second circuit comprises a transformer, in particular a planar transformer.

In an example, the transformer comprises at least two-windings.

In an example, at least one access terminal of the second circuit is directly connected, in particular soldered, to the first access terminal on the first side of the integrated electronic device.

In an example, the power converter device comprises a conductive interposing element, in particular a copper plate or pillar, arranged between the integrated electronic device and the second circuit.

In an example, the power converter comprises a plurality of switching cells and is configured as a full-bridge to full-bridge DC-DC converter. In this example a first full bridge may comprise a standard MOSFET full bridge, and a second full bridge may comprise four-quadrant devices. Alternatively, the first and the second full bridge can comprise standard MOSFET full bridges.

In an example, the first substrate and the second substrate are each configured as Printed Circuit Board, PCB, board.

The invention also relates to the use of a dissipative package, in particular to a dual side cooling package, in a power converter device according to techniques herein.

In accordance with some embodiments described herein, a design is proposed including a compact size, enhanced switching performance, reduced conduction and termination losses, and improved cost efficiency.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being

placed upon illustrating principles of the invention. Moreover, in the figures, like reference numerals designate corresponding parts. In the drawings:

FIG. 1(A) schematically illustrates a top view of a prior art assembly of a power converter device as discussed herein;

FIG. 1(B) schematically illustrates a bottom view of the prior art assembly of the power converter device shown in FIG. 1(A) as discussed herein;

FIG. 2(A) schematically and exemplarily illustrates an equivalent circuit of a power converter device in accordance with a first embodiment as discussed herein;

FIG. 2(B) schematically and exemplarily illustrates a switching cell arranged in an integrated electronic device as discussed herein;

FIG. 2(C) schematically and exemplarily illustrates a switching cell according to a first configuration as discussed herein;

FIG. 2(D) schematically and exemplarily illustrates a switching cell according to a second configuration as discussed herein;

FIG. 2(E) schematically and exemplarily illustrates a top view of the first substrate of the power converter device in accordance with the first embodiment as discussed herein;

FIG. 2(F) schematically and exemplarily illustrates a bottom view of the second substrate of the power converter device in accordance with the first embodiment as discussed herein;

FIG. 2(G) shows a sectional view through electronic devices arranged on the first substrate, and connected to respective electric contact patches of the second substrate as discussed herein;

FIG. 2(H) schematically and exemplarily illustrates a side view of the power converter device in accordance with the first embodiment as discussed herein;

FIG. 2(I) schematically and exemplarily illustrates a perspective of the power converter device in accordance with the first embodiment as discussed herein;

FIG. 3(A) schematically and exemplarily illustrates an equivalent circuit of a power converter device in accordance with a second embodiment as discussed herein;

FIG. 3(B) schematically and exemplarily illustrates a top view of the first substrate of the power converter device in accordance with the second embodiment as discussed herein;

FIG. 3(C) schematically and exemplarily illustrates a bottom view of the second substrate of the power converter device in accordance with the second embodiment as discussed herein;

FIG. 3(D) schematically and exemplarily illustrates a side view of the power converter device in accordance with the second embodiment as discussed herein;

FIG. 4 schematically and exemplarily illustrates a perspective of the power converter device in accordance with a third embodiment as discussed herein;

FIG. 5 schematically and exemplarily illustrates a perspective of the power converter device in accordance with a fourth embodiment as discussed herein;

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above”, “horizontal”, “vertical” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements have been designated by the same references in the different drawings if not stated otherwise.

In this specification, the term “substrate” can be general understood as a layer of insulating material on which components of the power converter device are mounted. The components can be interconnected on the substrate by means of interconnecting elements, such as conducting paths. In an example, the first substrate and the second substrate are each configured as Printed Circuit Board, PCB, boards.

The term “switching cell” as used herein can be used for referring to an electronic switch such as a diode, or a transistor configured for aperiodic or periodic switching.

The term “gate driver” which is used in this specification can be understood as a power amplifier circuit that accepts a low-power input, for example from a controller, and produces a high-current drive input for the switching cells, such as for the gate of a MOSFET transistor which can be implemented as switching cell. The gate driver can be seen as the interface between control signals (of a digital or an analog controller) and the switching cell. The control signals can be periodic signals originating from a microcontroller.

The term “power converter device” as used in this specification intends to describe a device that converts a source of current from one voltage level to another. In examples the device is a direct current, DC, to-DC converter. In alternative examples the device can be a DC to AC, AC to DC, or AC to AC converter. The device can be a semiconductor device and can be configured to convert a voltage of 48 V to 12 V, or 48 V to 1 V.

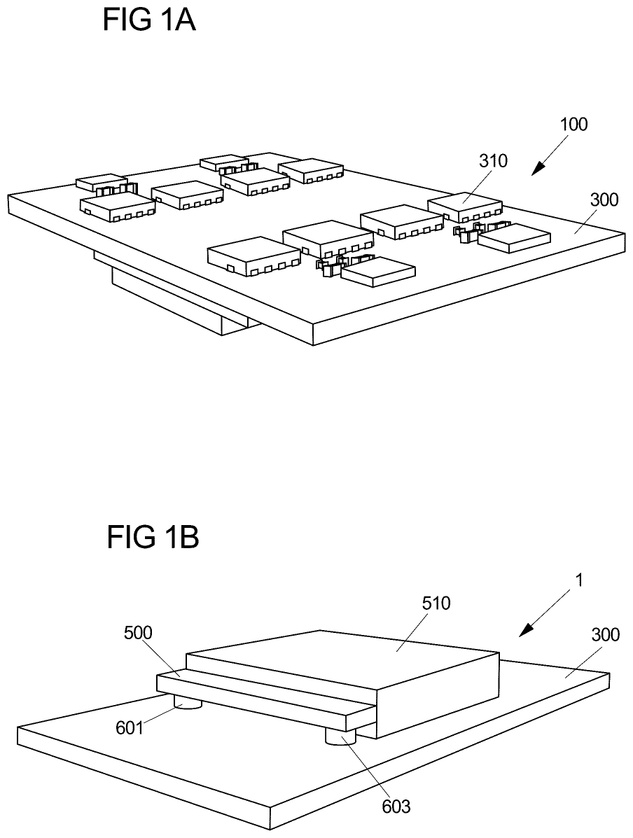

A prior art power converter device 100 that is located on two substrates is shown in FIGS. 1A and 1B, where opposite sides of the power converter device 100 are shown in FIGS. 1A and 1B. In the shown prior art example, a first substrate 300 comprising a first circuit 310, and a second substrate 500 comprising a second circuit 510 are interconnected through mechanical parts 601, 603, which are shown as copper blocks. The substrates 300, 500 in the prior art example are realized as PCB boards, and the first circuit 310 comprises two full-bridges of a full-bridge to full-bridge DC to DC power converter. The second circuit 510 comprises a planar transformer. However, the shown prior art approach, where the substrates 310, 510 are mechanically and/or electronically interconnected with mechanical parts 601, 603 as shown in FIGS. 1A and 1B, requires a rather sophisticated, multi-stage, manufacturing process.

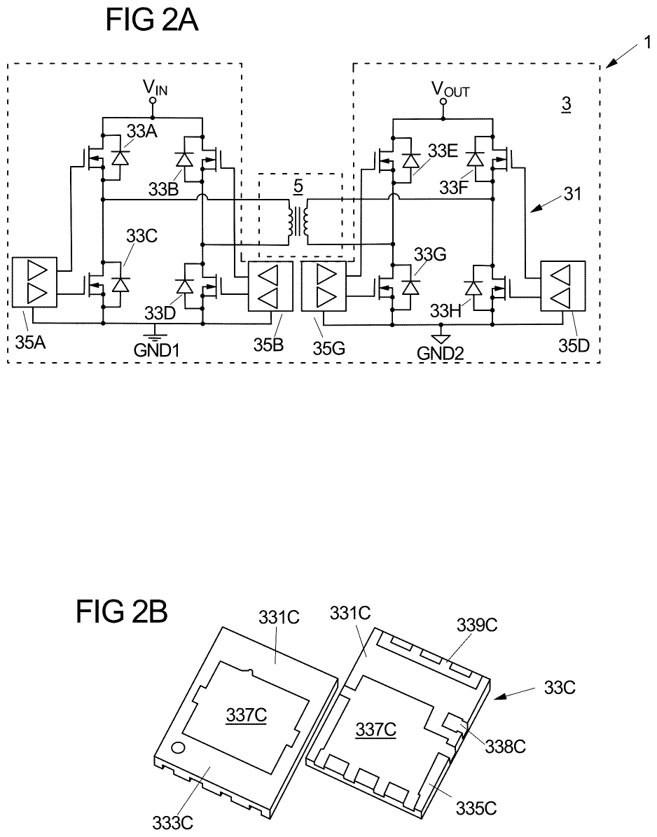

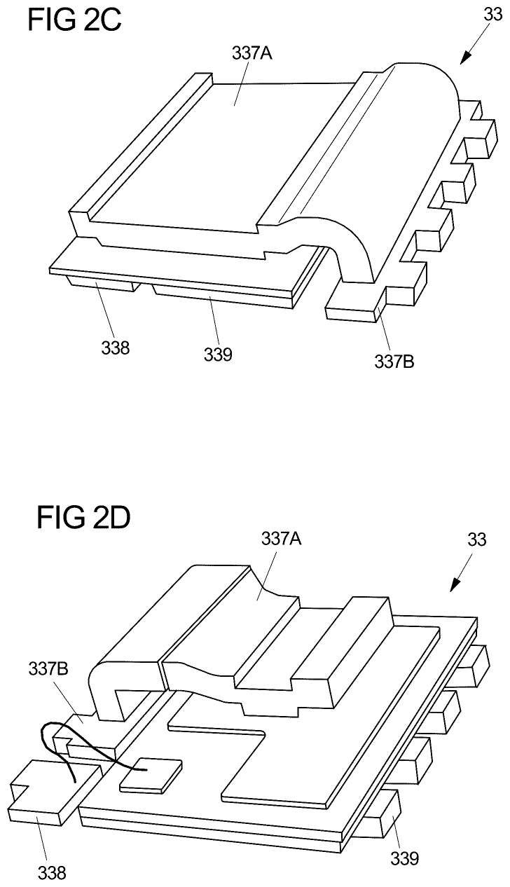

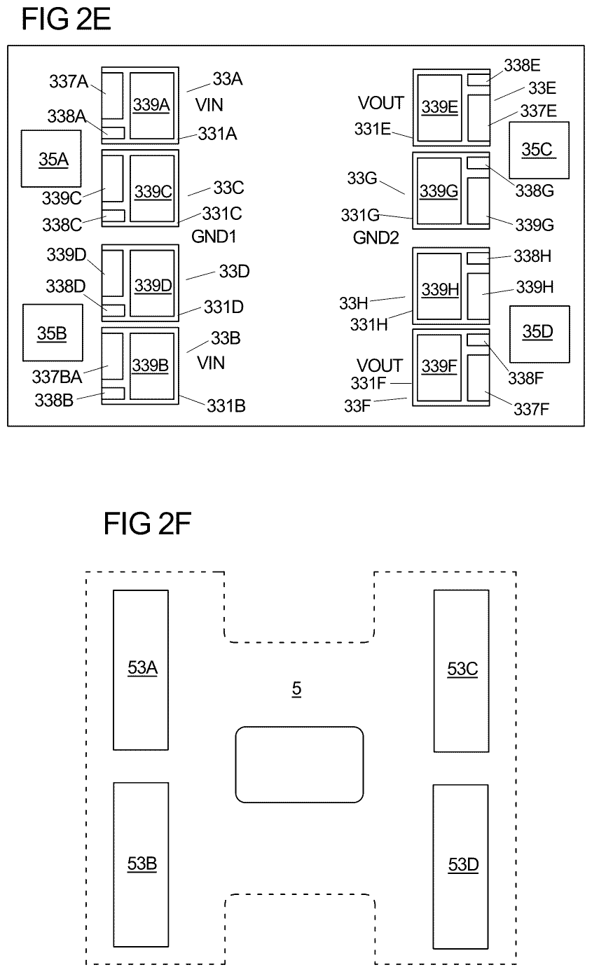

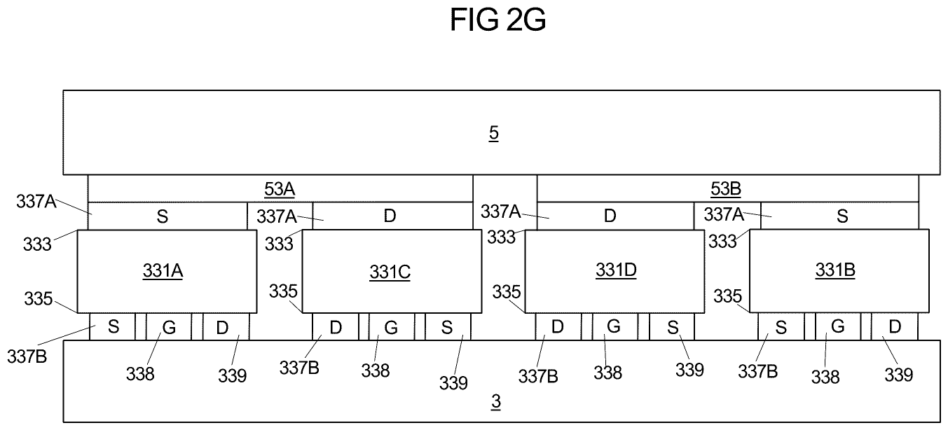

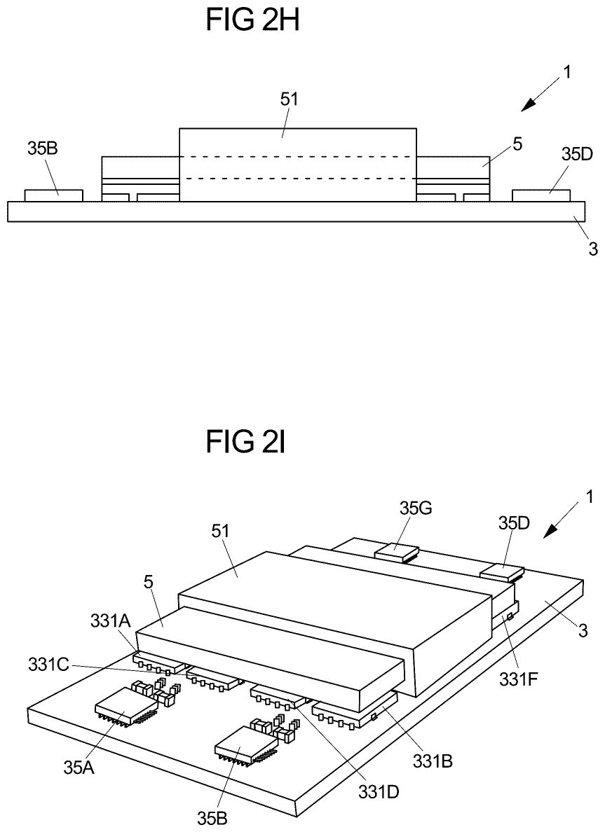

Referring first to FIGS. 2A-2I , a first embodiment of the power converter device 1, which is configured as a DC to DC power converter shall be explained:

FIG. 2A shows an equivalent circuit of the power converter device 1. The power converter device 1, comprises, e.g., on a first substrate 3 (first dotted boundary box) a first circuit 31, comprising eight switching cells 33A-33H, which are each arranged as semiconductor material in at least one integrated electronic device. In the shown embodiment, each switching cell 33A-33H comprises a MOSFET transistor.

In the power converter device 1 shown in FIG. 2A the switching cells 33A-33H are arranged on the first substrate 3 as two full bridges. The first substrate 3 further comprises four gate driver circuits 35A-35D which are connected to the gates of the MOSFET transistors in the switching cells 33A-33H. The gate driver circuits 35A-35D can be provided either in the housing of the integrated electronic devices or as a discrete module mounted on the first substrate 3.

The power converter device 1 further comprises a second substrate 5 (second dotted boundary box), which is of the same type than the first substrate 3 in the shown embodiment, i.e. both substrates 3, 5 are PCB substrates. In alternative embodiments the first substrate 3 and the second substrate 5 can be of different types. A second circuit 51 is mounted on the second substrate 5 and comprises in the shown embodiment a transformer 511. The transformer 511 can be a planar transformer which allows to transform the voltage and allows galvanic isolation between the input side and the output side of the power converter device 1. In the shown embodiment, the transformer 511 comprises two-windings. In alternative embodiments the transformer 511 can comprise more than two windings, such as for example three windings. Furthermore, the second circuit 51 can alternatively or additionally comprise components such as, capacitors, C, inductors, L, and/or LC circuits. For example, the transformer 511 in the second circuit 51 can comprise a so-called resonant tank in primary comprising a capacitor and inductances, and center-tapped windings in secondary. Alternatively, the second circuit 51 could comprise a transformer with a resonant tank in primary, and single winding secondary, or a transformer comprising two secondary tanks. Also shown in FIG. 2A are the input voltage, V_{IN}, tabs, output voltage, V_{OUT}, tabs and the respective ground tabs, GND₁, GND₂ of the power converter device 1.

FIG. 2B shows opposite surfaces 333, 335 of a switching cell 33 arranged in an integrated electronic device 331 comprising a first surface 333 and an opposite second surface 335. The shown switching cell 33 which is arranged in the integrated electronic device 331 is used in the first embodiment as shown in FIG. 2E. The integrated electronic device 331 is configured as dissipative package, as a so-called dual side cooling package, encapsulating the semiconductor material in an insulating material. The side cooling package can be, for example, a so-called OptiMOS™ package. The integrated electronic device 331 comprises a first access terminal 337A on the first surface 333, and three second access terminals 337B, 338, 339 on the second surface 335. One of the second access terminals 337B is shown with the same reference number, i.e. reference number 337, as first access terminal 337A, because both access terminals 337A, 337B are electrically connected with each other.

In a first configuration of the switching cell 33 which comprises a MOSFET transistor, the first access terminal 337A and the first, second access terminal 337B are the drain access terminal of the MOSFET transistor, the second, second access terminal 338 is the gate access terminal of the MOSFET transistor, and the third, second access terminal 339 is the source access terminal of the MOSFET transistor. In a second configuration of the switching cell 33, the first access terminal 337A and the first, second access terminal 337B are a source access terminal of the MOSFET transistor, the second, second access terminal 338 is a gate access terminal of the MOSFET transistor, and the third, second access terminal 339 is a drain access terminal of the MOSFET transistor.

Two configurations of a switching cell not included in an integrated electronic device according to the first and second configuration are shown in FIGS. 2C and 2D.

The first configuration shown in FIG. 2C can be also referred to as a source-down configuration, where the first access terminal 337A and the first, second access terminal 337B are the drain access terminals of the MOSFET transistor, the second, second access terminal 338 is the gate access terminal of the MOSFET transistor, and the third, second access terminal 339 is the source access terminal of the MOSFET transistor.

The second configuration shown in FIG. 2D can be also referred to as a drain-down configuration, where the first access terminal 337A and the first, second access terminal 337B are the source access terminals of the MOSFET transistor, the second, second access terminal 338 is the gate access terminal of the MOSFET transistor, and the third, second access terminal 339 is the drain access terminal of the MOSFET transistor.

In the configurations shown above in FIG. 2C and FIG. 2D, the second access terminals 337B, 338, 339 can be located on a lead frame so that the MOSFET transistor can be mounted on the substrate. The first access terminal 337A can be also referred to as clip, and can be realized as a copper clip, and allows a vertical current flow through the MOSFET transistor. In addition, the clip enables cooling from both sides of the MOSFET transistor, which improves thermal performance.

FIG. 2E shows a top view of the first substrate 3 of the power converter device 1 in accordance with the first embodiment. Switching cells 33A, 33B, 33E, 33F are configured in a drain down configuration and switching cells 33C, 33D, 33G, 33H are configured in a source down configuration and are arranged in integrated electronic devices 331A-331F as shown in FIG. 2B. Switching cells 33A, 33B, 33E, 33F which are configured in a drain down configuration and switching cells 33C, 33D, 33G, 33H which are configured in a source down configuration are arranged in the same type of electronic device 331. Only the second access terminals are indicated in FIG. 2E which are connected to conducting paths on the substrate 3 for interconnecting the elements as shown in the equivalent circuit of FIG. 2A. In FIG. 2E the second access terminals are indicated as Source, S, Drain, D, and Gate, G. Accordingly, the first access terminals of switching cells 33A, 33B, 33E, 33F are accessible on the top side of the switching cells 33A, 33B, 33E, 33F as source access terminals. Consequently, the first access terminals of switching cells 33C, 33D, 33G, 33H are accessible on the top side of the switching cells 33C, 33D, 33G, 33H as drain access terminals.

Also, shown in FIG. 2E are the four gate driver circuits 35A-35D which are connected to the gate access terminals, G, of the MOSFET transistors in the switching cells 33A-33H arranged in the integrated electronic devices 331A-331F.

FIG. 2F shows a bottom view of the second substrate 5 of the power converter device 1 in accordance with the first embodiment. The transformer is arranged on the opposite side of the second substrate 5 and is not visible in FIG. 2F. In further examples, the transformer could be also located on the inside of the second substrate 5 or arranged around the second substrate 5. The ends of the two transformer coils are led to though vias, i.e. holes in a material of the second substrate 5 to the bottom side of the second substrate 5 where they are each electrically connected to the contact patches 53A-53D. The contact patches 53A 53D comprise conductive material, such as copper, for electrically connecting the transformer coils via the contact patches 53A-53D.

For assembling the power converter 1, the first access terminals of switching cells 33A-33H are electrically and mechanically connected to the contact patches 53A 53D on the second substrate 5 in correspondence with the equivalent circuit shown in FIG. 2A. The electrical and mechanical connection can be made by directly soldering the first access terminals to the respective contact patches 53A-53D.

FIG. 2G shows a sectional view in a vertical direction through integrated electronic devices 331A-331D arranged on the first substrate 3 as shown in FIG. 2E, and connected to the respective electric contact patches 53A, 53B of the second substrate 5 as shown in FIG. 2F.

In FIG. 2G the second access terminals 337B, 338, 339 of electronic devices 331A-331D, of the MOSFET transistors, respectively, are shown next to each other to facilitate understanding of this invention. In examples of the invention, the second access terminals 337B, 338, 339 can be dispersed on the second surface 335 of the electronic devices 331A-331D as shown in FIG. 2B. In FIG. 2G the access terminals are referenced by numerals 337A, 337B, 338, 339 and by indicating the access terminals as Source, S, Drain, D, and Gate, G to facilitate understanding of the invention. In the embodiment shown in FIG. 2E, the second access terminals 337B, 338, 339 are connected to the substrate 3, i.e. to conducting paths on the substrate 3, while the first access terminals 337A of the shown electronic devices 331A-331D, which are located on a respective first surface 333 of the electronic devices 331A-331D are connected to the electric contact patches 53A, 53B of the second substrate 5 as shown in FIG. 2G in correspondence with the equivalent circuit of FIG. 2A

In FIG. 2H a side view of the assembled power converter device 1 in accordance with the first embodiment is shown, and FIG. 2I shows a perspective view of the power converter device 1 in accordance with the first embodiment, where the first substrate 3 and the second substrate 5 are connected to each other through a direct connection of the integrated electronic devices 331A-331F and the second circuit 51. Here, the first substrate 3 and the second substrate 5 are bridged through the top side, i.e. the first access terminals of the integrated electronic devices 331A-331F. This configuration allows a reduced footprint in correspondence with lateral layouts known in the prior art. Due to the vertical current flow through the MOSFET transistors, the heat distribution in power converter device 1 can be improved and conduction losses and loop inductances from the access terminals of the MOSFET transistors used inside the integrated electronic devices 331A-331F can be reduced/eliminated. In addition, the configuration described herein can be manufactured using standard PCB manufacturing methods.

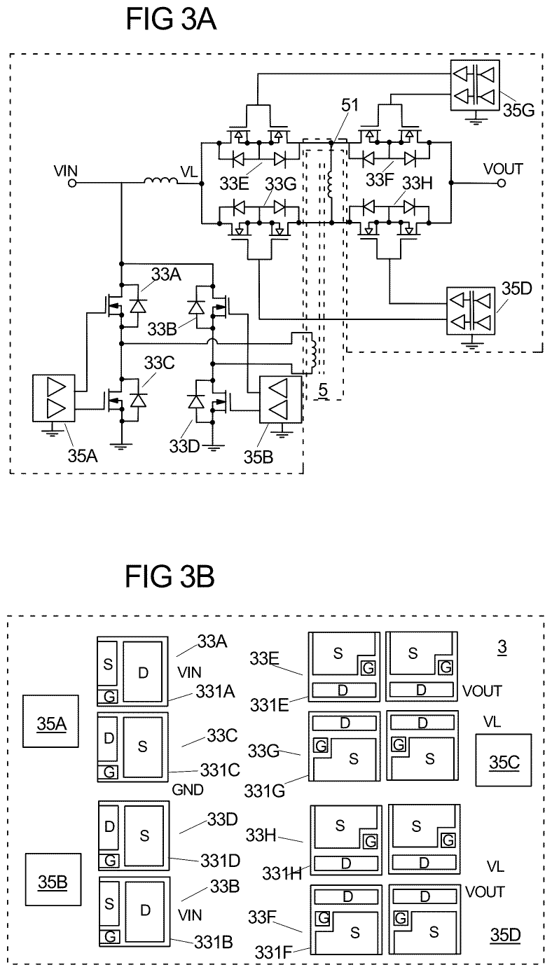

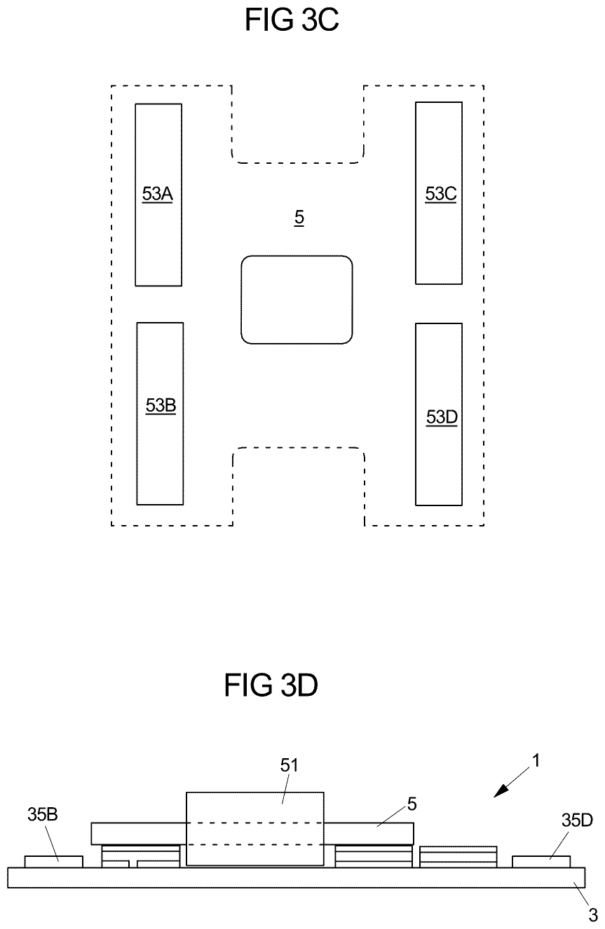

FIG. 3A shows an equivalent circuit of a power converter device 1 in accordance with a second embodiment. The equivalent circuit shown in FIG. 3A distinguishes from the equivalent circuit of the first embodiment shown in FIG. 2A in that only one of the two full bridges comprising switching cells 33A-33D including MOSFET transistors. The second full bridge in the second embodiment comprises switching cells 33E-33H including four-quadrant devices.

FIG. 3B shows a top view of the first substrate 3 of the power converter device 1 in accordance with the second embodiment. The switching cells 33A-33H are arranged on the first substrate 3 in accordance with the equivalent circuit shown in FIG. 3A. The second access terminals, which are located on the second side of the switching cells 33A-33H in the integrated electronic devices 331A-331F are denoted in FIG. 3B as source, S, drain, D, and gate, G.

As shown, the inventive concept of the present invention is adaptable and can be also applied to topologies different than the topology described in the first embodiment.

FIG. 3C shows a bottom view of the second substrate 5 of the power converter device 1 in accordance with the second embodiment. The second substrate 5 is similar to the second substrate 5 of the first embodiment, only the geometry of the contact patches 53A-53D and the distance between the contact patches 53A-53D can vary to electrically and mechanically contact the switching cells 33A-33H of the second embodiment, which are arranged on the respective first substrate 3.

FIG. 3D shows a side view of the power converter device 1 in accordance with the second embodiment.

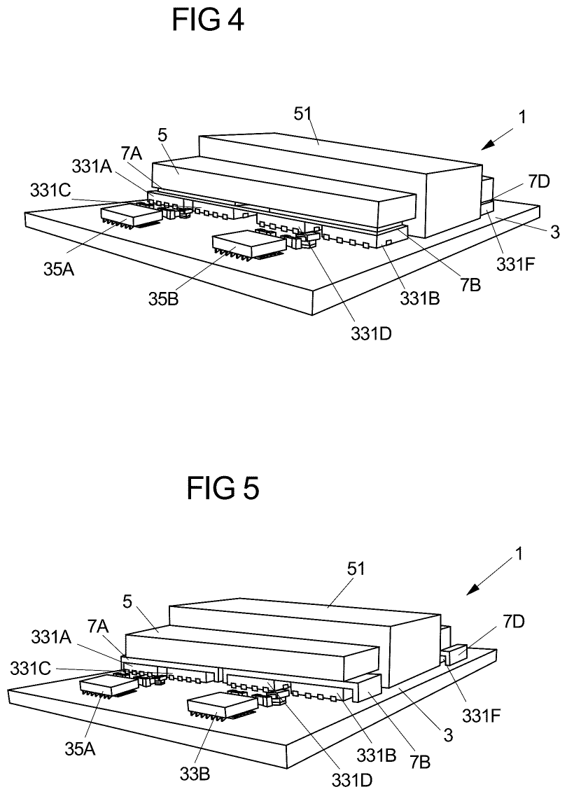

FIG. 4 shows a perspective of the power converter device 1 in accordance with a third embodiment. The power converter device 1 of the third embodiment differs from the power converter device of the first and second embodiment in that the first substrate 3 and the second substrate 5 are not connected to each other through a direct connection of the integrated electronic devices and the second circuit 51. Instead, the power converter device 1 comprises conductive interposing elements 7A-7D, which are realized as flat copper plates and are arranged between the access terminals on the integrated electronic devices 331A-331F and the contact patches of the second circuit 51. The first access terminals can be soldered onto one side of the respective conductive interposing elements 7A-7D and the contact patches of the second circuit 51 can be soldered onto the opposite side of the respective conductive interposing elements 7A-7D.

The conductive interposing elements 7A-7D can be customized in height to create space for taller components to be placed between first substrate 3 and the second substrate 5. Also, conductive interposing elements 7A-7D comprising copper can act as heat spreader and provide additional thermal enhancements. In addition, the interposing elements 7A-7D can contribute to the mechanical stability of the assembly and can be used to mitigate reliability issues, such as those arising from thermal cycling.

FIG. 5 shows a perspective of the power converter device 1 in accordance with a fourth embodiment employing conductive interposing elements 7A-7D. In the embodiment of FIG. 5, the conductive interposing elements 7A-7D are realized as u-shaped copper elements and are arranged between the integrated electronic devices and the contact patches of the second circuit 51. The u-shaped copper elements can increase the mechanical stability, release thermomechanical stresses on the access terminals, and ease mechanical assembly.

As described above, the conductive interposing elements 7A-7D of embodiments 3 and 4 can be used with the power converter devices 1 according to embodiments 1 and 2.

1. A power converter device comprising:
a first substrate comprising a first circuit, wherein the first circuit comprises at least one switching cell, which is arranged as semiconductor material in at least one integrated electronic device; and
a second substrate comprising a second circuit, wherein the first substrate and the second substrate are connected to each other through a connection of the integrated electronic device and the second circuit.

2. The power converter device as in claim 1, wherein the switching cell comprises a Metal-Oxide-Semiconductor Field-Effect-Transistor.

3. The power converter device as in claim 1, wherein the integrated electronic device is configured as a dissipative package, the dissipative package being a dual sided cooling package, the dual sided cooling package encapsulating the semiconductor material.

4. The power converter device as in claim 1, wherein a first side of the integrated electronic device includes at least a first access terminal of the first circuit, wherein the first access terminal is connected to the second circuit.

5. The power converter device as in claim 4, wherein a second side, which is facing opposite the first side, includes a second access terminal, the second access terminal including a source terminal, wherein the second access terminal is connected to a strip conductor disposed on the first substrate.

6. The power converter device as in claim 1, wherein the second circuit comprises a a planar transformer.

7. The power converter device as in claim 6, wherein the transformer comprises at least two-windings.

8. The power converter device as in claim 7, wherein at least one access terminal of the second circuit is directly soldered to the first access terminal on the first side of the integrated electronic device.

9. The power converter device as in claim 7, wherein a conductive interposing element is disposed between the integrated electronic device and the second circuit.

10. The power converter device as in claim 1, wherein the power converter device comprises a plurality of switching cells and is configured as a full-bridge to full-bridge DC-DC converter including a first full bridge and the second full bridge.

11. The power converter device as in claim 10, wherein the first full bridge comprises a standard MOSFET full bridge, and the second full bridge comprises four-quadrant devices.

12. The power converter device as in claim 1, wherein the first substrate is a first printed circuit board and the second substrate is a second printed circuit board.
